(19) United States
(12) Patent Application Publication
(10) Pub. No.: US 2009/0266703 A1
(43) Pub. Date: Oct. 29, 2009

(54) PLASMA GENERATING DEVICE AND FILM DEPOSITION METHOD IN WHICH THE PLASMA GENERATING DEVICE IS USED

(76) Inventors: Nan Jiang, Osaka (JP); Hong-Xing Wang, Osaka (JP); Akio Hiraki, Hyogo (JP); Masanori Haba, Osaka (JP)

Correspondence Address: MCDERMOTT WILL & EMERY LLP, 600 13TH STREET, N.W., WASHINGTON, DC, 20005-3096, US

(21) Appl. No.: 11/997,697

(22) PCT Filed: Jul. 31, 2006
(86) PCT No.: PCT/JP2006/315109

§ 371 Date: Feb. 1, 2008

(30) Foreign Application Priority Data
Aug. 2, 2005 (JP) 2005-224355
Aug. 2, 2005 (JP) 2005-224356
Aug. 2, 2005 (JP) 2005-224357
Oct. 28, 2005 (JP) 2005-313867

(51) Int. Cl. C23C 14/34; C23C 14/56

(52) U.S. Cl. 204/192.12; 204/298.02

(57) ABSTRACT

Problem: To generate long plasma easily at low cost and to perform a plurality of film deposition methods using a single plasma generating device.

Means for Solving the Problem A plasma generating device is provided with, in the vacuum inside thereof, a cylindrical electrode comprising an opening in a part thereof and generating plasma therein when gas is introduced thereinto and a direct-current negative voltage is applied thereto.

### FIELD OF THE INVENTION

The present invention relates to a plasma generating device for generating plasma by applying a voltage to an electrode placed in the vacuum inside of the device and a film deposition method in which the plasma generating device is used.

### BACKGROUND OF THE INVENTION

The plasma can be used for the formation of a thin film in the manufacturing of a semiconductor, a display element, a magnetic recording element, an abrasion-resistant element and the like.

In the case where the film is formed on a surface of a substrate which is long in a direction such as wire, a plasma generating device capable of generating long plasma is necessary.

Examples of the film deposition using the plasma include PVD (Physical Vapor Deposition) and CVD (Chemical Vapor Deposition). The respective film deposition methods need different film deposition devices.
Patent Document 1: No. 2004-216246 of the Japanese Patent Applications Laid-Open
Patent Document 2: No. 2980058 of the Japanese Patent Documents
Patent Document 3: No. H10-203896 of the Japanese Patent Applications Laid-Open
Patent Document 4: No. 2004-190082 of the Japanese Patent Applications Laid-Open

### DISCLOSURE OF THE INVENTION

### Problem to be Solved by the Invention

A main object of the present invention is to provide a plasma generating device capable of forming a film in a simplified and inexpensive manner on a target having a long length and adaptable to different film deposition methods, and a film deposition method in which the plasma generating device is used.

### Means for Solving the Problem

1) A plasma generating device according to the present invention is provided with a cylindrical electrode in the vacuum inside thereof, wherein gas is introduced into the cylindrical electrode and a direct-current negative voltage is applied to the cylindrical electrode as a plasma generating voltage.

The cylindrical electrode preferably comprises a peripheral wall having at least a coil shape, a net shape, a barrier shape or a basket shape.

The cylindrical electrode is preferably open at each end and linearly extends towards each end so as to allow a film deposition target having a plate shape or a wire shape to be placed inside thereof.

The cylindrical electrode is preferably formed from metal.

The cylindrical electrode is preferably formed from solid carbon.

The cylindrical electrode preferably has a circular sectional surface.

The cylindrical electrode preferably has a polygonal sectional surface.

According to the plasma generating device of the present invention, wherein the cylindrical electrode is used, the cylindrical electrode can be formed into a long cylindrical shape in compliance with a film deposition target in the case where the target has such a long shape as the plate shape or the wire shape, and the film deposition target can be placed inside the device for the film deposition.

Accordingly, in the case where plasma having a long length is necessary in order to form the film on the film deposition target, the cylindrical electrode can be extended to have a long length so that the long plasma can be generated. In order to generate the long plasma, it is only necessary to extend the length of the cylindrical electrode. As a result, cost for generating the long plasma can be controlled.

According to the present invention, wherein both ends of the cylindrical electrode are open and the film deposition target is inserted into the cylindrical electrode, in the case where the film deposition target is long like a wire, the cylindrical electrode and the film deposition target can be moved in relation to each other, and the film can be inexpensively formed on the long film deposition target, eliminating the necessity of extending the length of the plasma.

According to the plasma generating device of the present invention, one device can be applied to a plurality of film deposition methods such as PVD, reactive PVD, and CVD by controlling the pressure and selecting a type of gas.

One end or both ends of the cylindrical electrode may be open or closed.

The shape of the film deposition target is not particularly limited.

Examples of the shape of the film deposition target include a plate shape, wire shape and the like.

The sectional shape of the film deposition target is not particularly limited.

Examples of the shape of the film deposition target include a circular shape, a semi-circular shape, an elliptical shape, a polygonal shape and the like.

The shape of the cylindrical electrode is not particularly limited.

In the case where the peripheral wall of the cylindrical electrode has a coil shape or a net shape, the plasma can be generated with a desired density through the adjustment of a spiral diameter and a spiral pitch. Further, a thermal expansion of the cylindrical electrode at the time when the plasma is generated can be efficiently absorbed and a stress resulting from the thermal expansion can be alleviated so that a life of the cylindrical electrode can be improved.

In the case where the peripheral wall of the cylindrical electrode has a barrier shape or a basket shape, the plasma can be evenly and densely generated between the cylindrical electrode and the film deposition target having a wire shape or a plate shape.

2) A plasma generating method according to the present invention, in which the plasma generating device recited in 1) is used, comprises a first step for placing the film deposition target inside the cylindrical electrode, a second step for reducing an internal pressure of the cylindrical electrode, a third step for introducing gas into the cylindrical electrode, and a fourth step for applying a direct-current negative voltage to the cylindrical electrode.

The plasma generating method preferably further comprises a fifth step for applying a bias voltage for controlling a film deposition speed to the film deposition target.

The plasma generating method preferably further comprises a sixth step for applying a bias voltage for controlling a film quality to the film deposition target.

### EFFECT OF THE INVENTION

According to the present invention, the long plasma can be easily and inexpensively generated. At the same time, in the present invention, one plasma generating device can be applied to a plurality of film deposition methods by controlling pressure and selecting a type of gas.

### BRIEF DESCRIPTION OF THE DRAWINGS

FIG. 1 shows an example of a plasma generating device according to a preferred embodiment of the present invention.

FIG. 2 shows an external appearance of the plasma generating device.

FIG. 3 shows a photograph of a state where the plasma is generated by the plasma generating device.

FIG. 3 shows a photograph of a state where the plasma is generated by the plasma generating device.

FIG. 4 shows a modified embodiment of a cylindrical electrode.

FIG. 5 shows another embodiment of the cylindrical electrode.

FIG. 6 shows still another embodiment of the cylindrical electrode.

FIG. 7 shows a side view of a cathode having a wire shape on which a carbon film is formed.

FIG. 7 shows a sectional view of a field emission lamp provided with the wire-shape cathode shown in FIG. 8.

FIG. 9 shows another example of the plasma generating device.

FIG. 10 shows still another example of the plasma generating device.

FIG. 11 is a SEM photograph showing the film deposition by the plasma generating device.

FIG. 12 is a sectional view showing a film deposition structure by the plasma generating device.

FIG. 13 shows a sectional shape of a carbon film having a needle shape shown in FIG. 12.

FIG. 14 shows still another example of the plasma generating device.

FIG. 15 shows still another example of the plasma generating device.

FIG. 16 shows still another example of the plasma generating device.

FIG. 17 shows still another example of the plasma generating device.

FIG. 18 is a graph in which a voltage of a bias power supply is shown in a horizontal axis and a speed of film deposition on a surface of a conductive wire is shown in a vertical axis, in the plasma generating device shown in FIG. 17.

FIG. 19 is a graph in which the voltage of the bias power supply is shown in a horizontal axis and the quality of a film on the surface of the conductive wire is shown in a vertical axis, in the plasma generating device shown in FIG. 17.

### DESCRIPTION OF REFERENCE SYMBOLS

10 plasma generating device
20 cylindrical electrode
22 conductive wire (film deposition target)

### PREFERRED EMBODIMENT OF THE PRESENT INVENTION

Hereinafter, a plasma generating device according to a preferred embodiment of the present invention is described referring to the drawings.

### Example of Plasma Generating Device

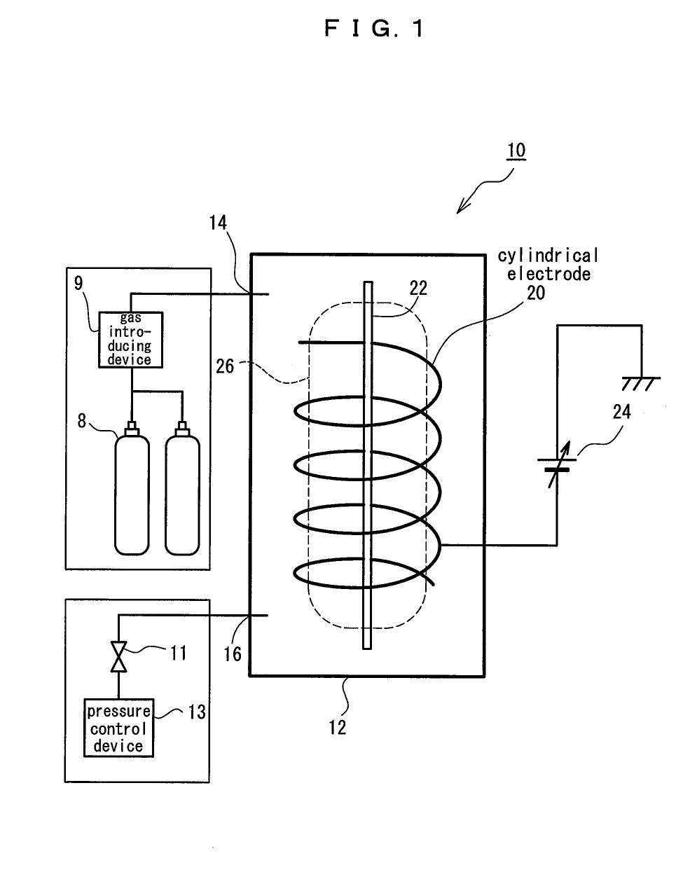

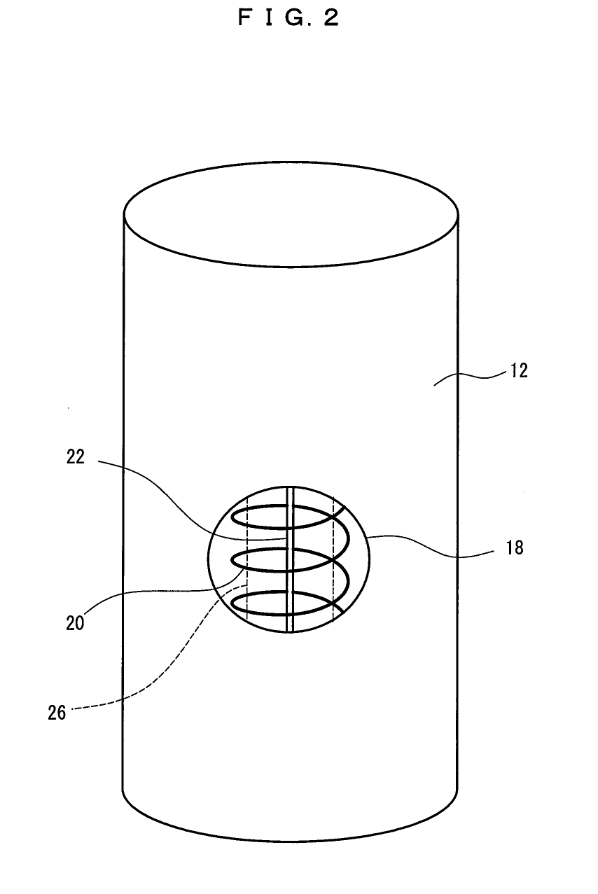

FIG. 1 shows a constitution of the plasma generating device, and FIG. 2 shows an external appearance of the plasma generating device. A plasma generating device 10 comprises a cylindrical vacuum chamber 12. The chamber 12 is conductive or electrically insulated. The chamber 12 comprises a gas introducing section 14 and a gas exhausting section 16. The chamber 12 comprises a visual-check window 18. A gas introducing device 9 is connected to the gas introducing section 14. The gas introducing device 9 selects gas corresponding to a type of film deposition method from a gas cylinder 8 and adjusts a pressure or a flow amount of the selected gas, and then, introduces the gas into the gas introducing section 14. The gas cylinder 8 can also be included in the gas introducing device. A pressure control device 13 is connected to the gas exhausting section 16 via an exhaust control valve (vacuum valve) 11. The pressure inside the cylindrical vacuum chamber 12 can be controlled to keep it in the range of 10 Pa to 10,000 Pa depending on an opening degree of the exhaust control valve 11 under the control by the pressure control device 13.

The plasma generating gas is, for example, non-reactive gas such as argon or helium in the case where the plasma generating device 10 according to the present preferred embodiment is used as a PVD device. The plasma generating gas is, for example, reactive gas such as oxygen in the case where the plasma generating device 10 according to the present preferred embodiment is used as a reactive PVD device, and, for example, carbon-based gas when used as a CVD device.

The internal pressure of the chamber 12 is appropriately set in the range of 10 Pa to 10,000 Pa. The internal pressure is set to, for example, at most 100 Pa in the case where the plasma generating device 10 according to the present preferred embodiment is used as the PVD device or the reactive PVD device, and to, for example, at least 500 Pa when used as the CVD device.

A cylindrical electrode 20 is provided inside the chamber 12.

The cylindrical electrode 20 is formed in a coil shape.

A conductive wire 22, which is a film deposition target, is provided in an internal space of the cylindrical electrode 20. The cylindrical electrode 20 is linearly extended in one direction. The internal space of the cylindrical electrode 20 constitutes a space for generating long cylindrical plasma extended in one direction. The conductive wire 22 is provided in the internal space and has a long and thin shape.

An inner peripheral surface of the cylindrical electrode 20 and an outer peripheral surface of the conductive wire 22 face each other with a predetermined space therebetween in the direction they are extended. One-end side of the cylindrical electrode 20 is connected to a negative electrode of a voltage-variable direct-current power supply 24, and a direct-current negative voltage is applied thereto.

In the plasma generating device 10 thus constituted, the chamber 12 is depressurized by the pressure control device 13 and the plasma generating gas is introduced from the gas introducing section 14, and then, the negative voltage of the direct-current power supply 24 is applied to the cylindrical electrode 20. As a result, plasma 26 is generated in the internal space of the cylindrical electrode 20.

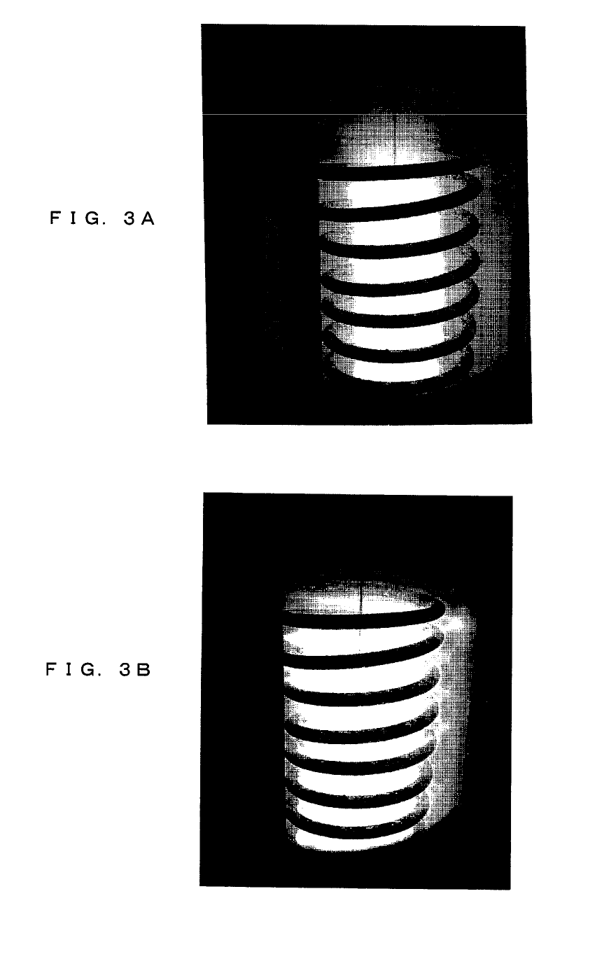

FIG. 3 show photographs of the generation of the plasma 26 in the internal space of the cylindrical electrode 20 in the plasma generating device 10. These photographs taken via the visual-check window 18 of the chamber 12 show the inside of the chamber 12. In the photograph of FIG. 3A, the voltage of the direct-current power supply 24 was 700 V, methane/hydrogen gas was selected as the gas to be introduced, and the pressure was 80 Pa. In the photograph of FIG. 3B, the voltage of the direct-current power supply 24 was 700 V, methane/hydrogen gas was selected, and the pressure was 170 Pa. A material of the cylindrical electrode 20 was SUS, and a material of the conductive wire 22 was nickel. Though the reference symbols cannot be shown in the photographs, the cylindrical electrode 20, wire 22 and plasma 26 in the chamber 12 can be clearly photographed via the visual-check window 18 from outside of the chamber 12.

A method of forming a film on a wire by the plasma generating device 10 is described below. The conductive wire 22 is placed inside of the cylindrical electrode 2. Both ends of the wire 22 may be connected to an alternate-current power supply 23 in order to heat the wire 22. The hydrogen gas and the methane gas are introduced through the gas introducing section 14.

When the internal pressure of the chamber 12 is reduced and the negative potential of the direct-current power supply 24 is applied to the cylindrical electrode 20, the plasma 26 is generated in the internal space of the cylindrical electrode 20, and the methane gas is thereby dissolved. As a result, a carbon film is formed on the surface of the wire 22.

In the photographs of FIG. 3, the conductive wire 22 is placed in the internal space of the cylindrical electrode 20 as a film deposition target. The carbon film could be formed on the surface of the conductive wire 22.

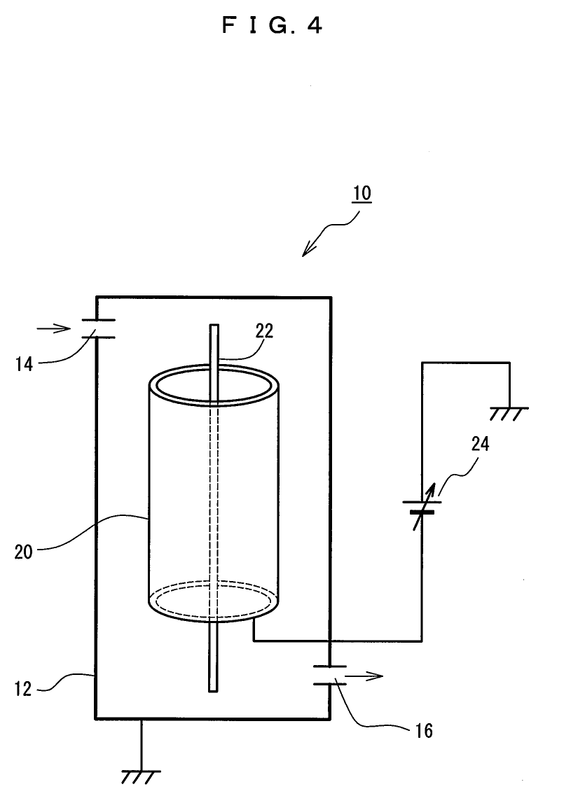

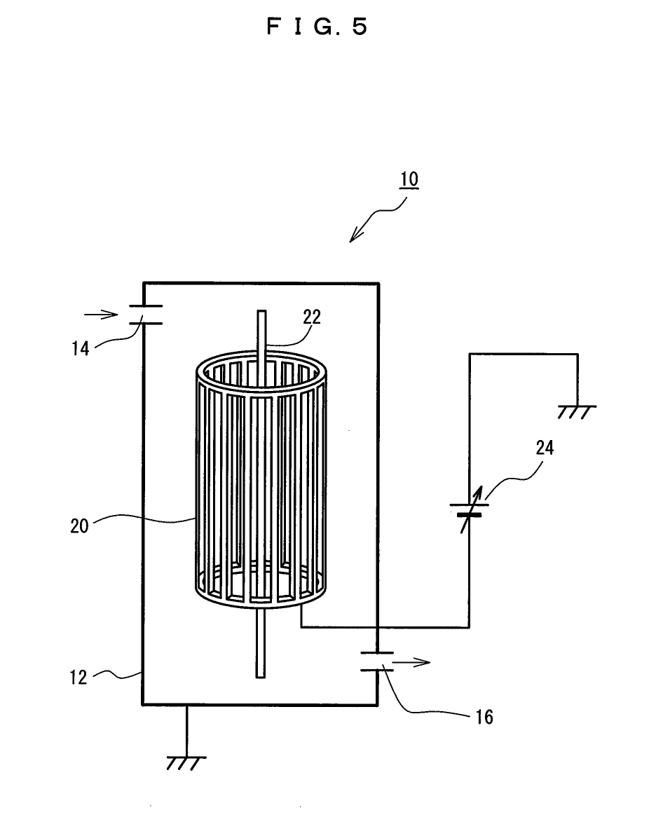

The cylindrical electrode 20 may have a closed cylindrical peripheral wall not provided with any opening as shown in FIG. 4, or a peripheral wall having a barrier shape circumferentially provided with a plurality of independent openings as shown in FIG. 5. A net shape may be adopted in place of the barrier shape.

The conductive wire 22 on which the carbon film is formed can be used as a cold cathode electron source. The cold cathode electron source can be incorporated into a field emission lamp. In the field emission lamp, electrons are emitted from the cold cathode electron source by the application of an electric field between the cold cathode electron source and an anode. The emitted electrons collide into phosphors and thereby excite the phosphors. As a result, light emission occurs.

Examples of the carbon film formed on the surface of the wire 22 include carbon nanotube, carbon nanowall film and needle-shape carbon film.

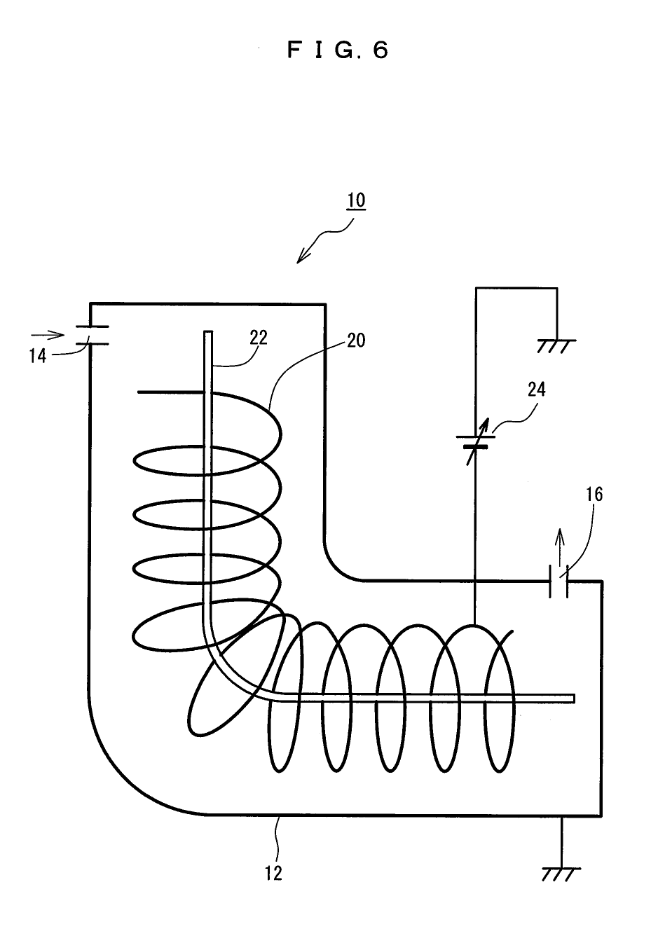

In the present preferred embodiment, the carbon film can be formed on the surface of the conductive wire 22 when the cylindrical electrode 20 is bent, and the conductive wire 22 is also bent so as to correspond to the bent shape of the cylindrical electrode 20 and placed in the cylindrical electrode 20 as shown in FIG. 6.

As described, according to the present preferred embodiment, the cylindrical electrode 20 has such a length as approximately 2 m, the conductive wire 22 as long as, for example, 2 m is placed in the cylindrical electrode 20, and the long plasma 26 is generated along the shape of the internal space of the cylindrical electrode 20 in the internal space of the cylindrical electrode 20. As a result, the carbon film can be formed on the surface of the conductive wire 22.

As described, according to the plasma generating device, one device can be applied to film deposition methods such as PVD, reactive PVD, and CVD when the pressure is controlled and the type of gas is selected. More specifically, firstly, the present plasma generating device vacuum-controls the pressure to form such a low pressure as at most 100 Pa using the pressure control device, introduces a non-reactive gas such as argon or helium using the gas introducing device, and applies direct-current negative voltage to the cylindrical electrode using the voltage applying device. Accordingly, the gas is converted into plasma inside of the cylindrical electrode 20 by a high electrical field therein, and gas molecular ions are thereby generated. The generated ions collide into the cylindrical electrode, being attracted by the negative potential of the cylindrical electrode, and atoms are thereby thrown (sputtered) out of the cylindrical electrode. The film is formed on the surface of the film deposition target by the sputtered atoms. In other words, the plasma generating device according to the present invention can be used as the PVD device.

Secondly, the present plasma generating device controls the pressure to form such a low pressure as at most 100 Pa using the pressure control device, introduces a reactive gas such as oxygen using the gas introducing device, and applies the direct-current negative voltage to the cylindrical electrode using the voltage applying device. Accordingly, the plasma is generated inside the cylindrical electrode. The generated plasma sputters the materials constituting the cylindrical electrode such as iron and nickel, and the film made of an oxide such as that of iron and nickel is formed on the surface of the film deposition target placed in the cylindrical electrode. In other words, the plasma generating device according to the present invention can be used as the reactive PVD device.

Thirdly, the present plasma generating device controls the pressure to form such a high pressure as at least 500 Pa using the pressure control device, introduces, for example, a mixed gas including hydrogen gas and methane gas using the gas introducing device, and applies the direct-current negative voltage to the cylindrical electrode using the voltage applying device. Accordingly, the plasma is generated inside the cylindrical electrode. The carbon film is formed by the generated plasma on the surface of the film deposition target placed in the cylindrical electrode. In other words, the plasma generating device according to the present invention can be used as the plasma CVD device.

In the present plasma generating device, in the case where, for example, carbon-compound-based gas is introduced into the cylindrical electrode so that the carbon film is formed on the surface of the film deposition target such as a long wire or base material, the film deposition can be realized in such a simplified manner that the cylindrical electrode is extended in accordance with the length of the film deposition target and the film deposition target is placed inside the cylindrical electrode. As a result, cost for the film deposition can be reduced.

The present plasma generating device can be applied to the manufacturing of a cold cathode electron source of a field emission lamp. In the cold cathode electron source, a carbon film comprising a plurality of fine protrusions is formed on the surface of the conductive wire.

The present plasma generating device, wherein carbon-based gas is introduced, can be used as a direct-current plasma CVD device for forming a carbon film on a surface of a film deposition target.

The present plasma generating device, wherein etching gas is introduced, can be used as a direct-current plasma etching device. The present plasma generating device, wherein plating gas is introduced, can be used as a direct-current plasma plating device.

A single present plasma generating device provided with a CVD gas cylinder, an etching gas cylinder and a plating gas cylinder can generate plasma of at least three different types of film deposition.

Another Example of Plasma Generating Device

In the plasma generating device 10 according to the present preferred embodiment, the cylindrical electrode 20 may be formed from solid carbon, in which case an entire electrode part of the cylindrical electrode 20 does not need to be formed from only solid carbon.

In the plasma generating device 10 according to the present preferred embodiment, hydrogen plasma is generated when hydrogen gas is used as the introducing gas. The hydrogen ions in the plasma collide into the cylindrical electrode 20, which is the solid carbon source where the direct-current negative voltage is applied, at a high speed. Energy generated by the collision makes carbon pop out of the cylindrical electrode 20. The popped carbon, which is target particles, is chemically combined (CHx) with the hydrogen ions in the plasma to form a hydrocarbon compound, which collides into the film deposition target placed inside the cylindrical electrode 20, which is, for example, the conductive wire 22. The hydrogen pops out of the hydrocarbon compound which has collided into the conductive wire 22, while the carbon remains on the surface of the conductive wire 22 and is deposited thereon. As a result, the carbon film is formed on the surface of the conductive wire 22.

According to the plasma generating device 10, the carbon film can be formed on the surface of the conductive wire 22 without the introduction of any gas. Further, the carbon film can be formed on the surface of the conductive wire 22 by the plasma PVD when argon gas, for example, is used as the introducing gas.

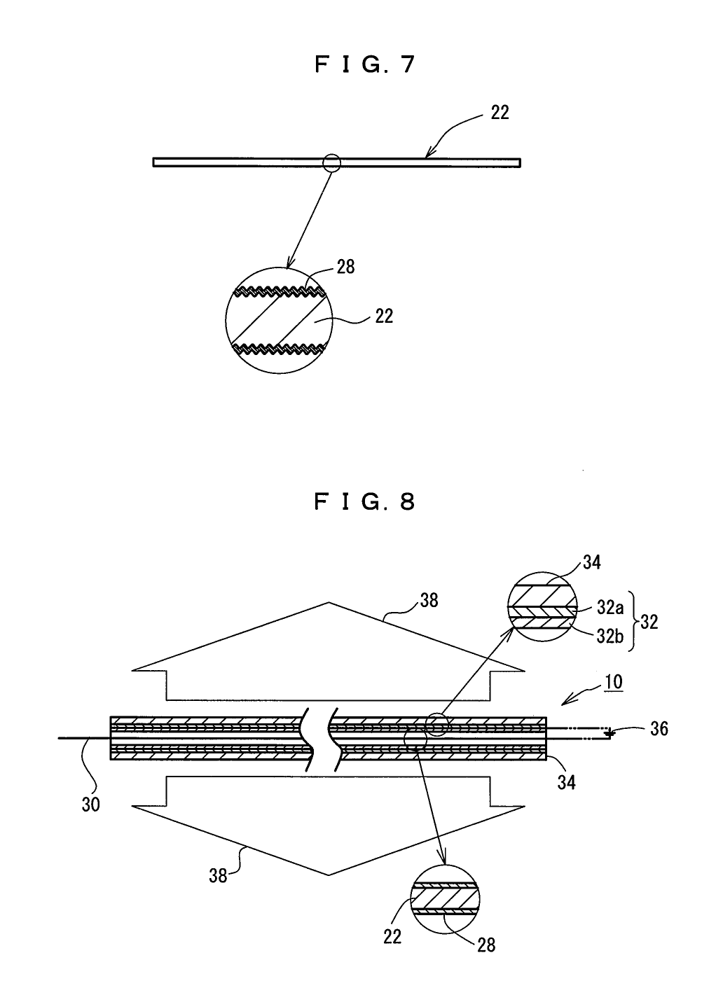

FIG. 8 shows a sectional structure of a field emission lamp provided with a wire 22, shown in FIG. 7, on which a carbon film 28 is formed as a wire-shape cathode 30.

As shown in FIG. 8, the field emission lamp comprises a wire-shape cathode 30 having a diameter of approximately 1-2 mm and a length of 6 cm to 2 m inside a lamp tube 34 having a diameter of 2-25 mm and a length of 6 cm-2 m. A phosphor-attached anode 32 is provided on an inner surface of the lamp tube 34. The phosphor-attached anode 32 comprises an anode 32a and a phosphor 32b. In a possible example of the field emission lamp shown in FIG. 8, gas which is excited by the collision of the electrons and generates ultraviolet ray is sealed into the lamp tube 34, and photoluminescence phosphor for converting the ultraviolet ray into visible light is provided on the inner peripheral surface of the lamp tube 34.

Apart from the foregoing, in the present preferred embodiment, though not shown, the carbon film can be formed on the surface of the conductive wire in such a manner that a pair of rectangular electrodes is provided so as to face each other inside the chamber, the conductive wire is provided in one of the electrodes, hydrogen gas and carbon-based gas are introduced into the chamber, and the direct-current negative voltage is applied to between the electrodes so that the plasma is generated.

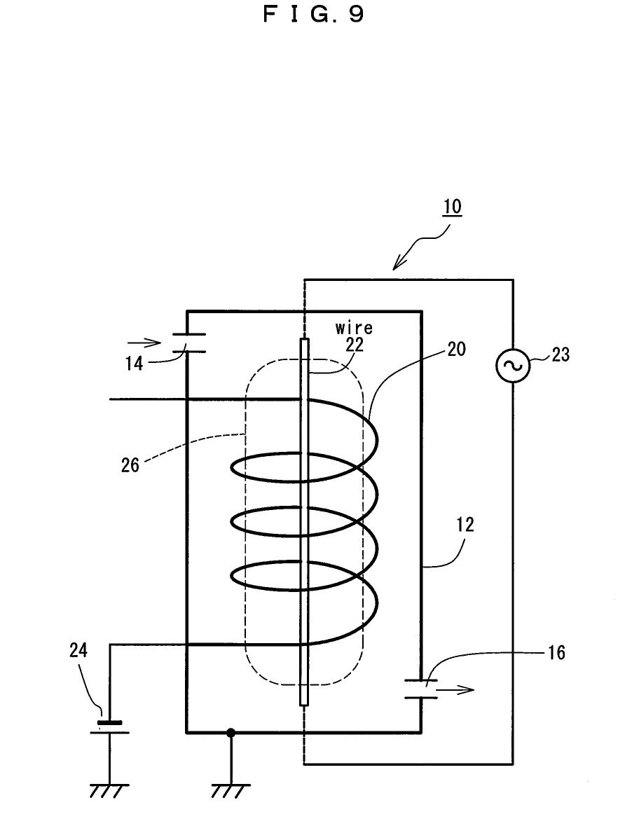

In the present preferred embodiment, the conductive wire 22 may be heated by the alternate current source 23 as shown in FIG. 9. A wire diameter of the coil constituting the cylindrical electrode 20 is, for example, 2 mm to 25 mm, and an inter-wire space of the coil is, for example, 2 mm to 20 mm.

Still Another Example of Plasma Generating Device

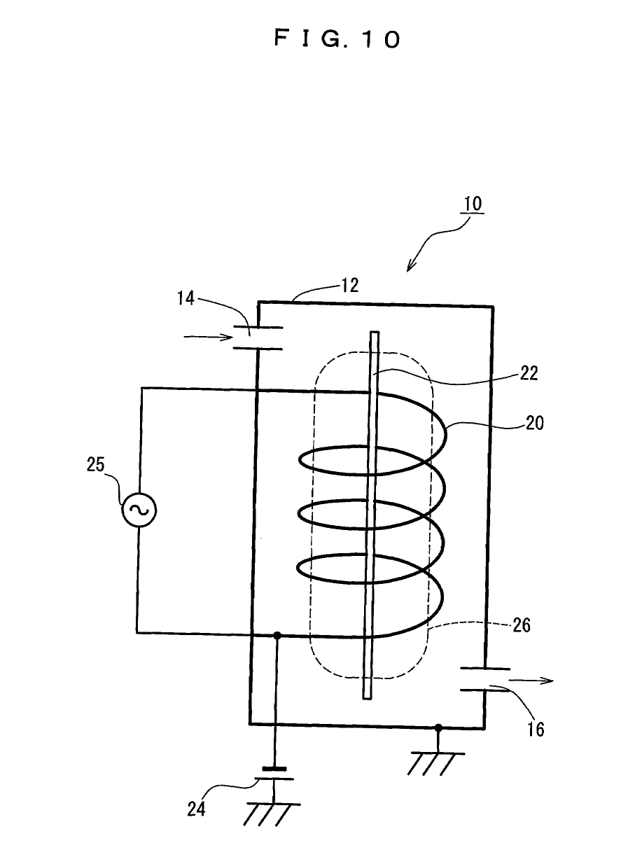

FIG. 10 shows still another example of the plasma generating device 10. In the present example, a high-frequency voltage is applied to both ends of the cylindrical electrode 20 from a high-frequency power supply 25. A power frequency of the high-frequency power supply 25 is, for example, 13.56 MHz, 4 MHz, 27.12 MHz, 40.68 MHz or the like. A voltage in which the high-frequency voltage is superposed on the direct-current negative voltage (superposition voltage) is applied to the cylindrical electrode 20. A positive electrode of the direct-current power supply 24 is grounded. The wire diameter and the inter-wire space of the coil constituting the cylindrical electrode 20 are not particularly limited.

In the plasma generating device 10 thus constituted, when the chamber 12 is depressurized so that methane gas and hydrogen gas are introduced as the introducing gas from the gas introducing section 14, and the superposition voltage is applied to the cylindrical electrode 20, the plasma 26 is generated inside the cylindrical electrode 20. Then, the carbon film is formed by the plasma 26 on the surface of the conductive wire 22 placed inside the cylindrical electrode 20.

FIG. 11 shows SEM photographs 1 and 2 of the carbon film formed under the following conditions. The SEM photograph 2 is a close-up picture of the SEM photograph 1. In the SEM photograph 1, the applied voltage between the anode and cathode is 30 kV, and a magnification is 1,000 times. The magnification of the SEM photograph 2 is 4,300 times.

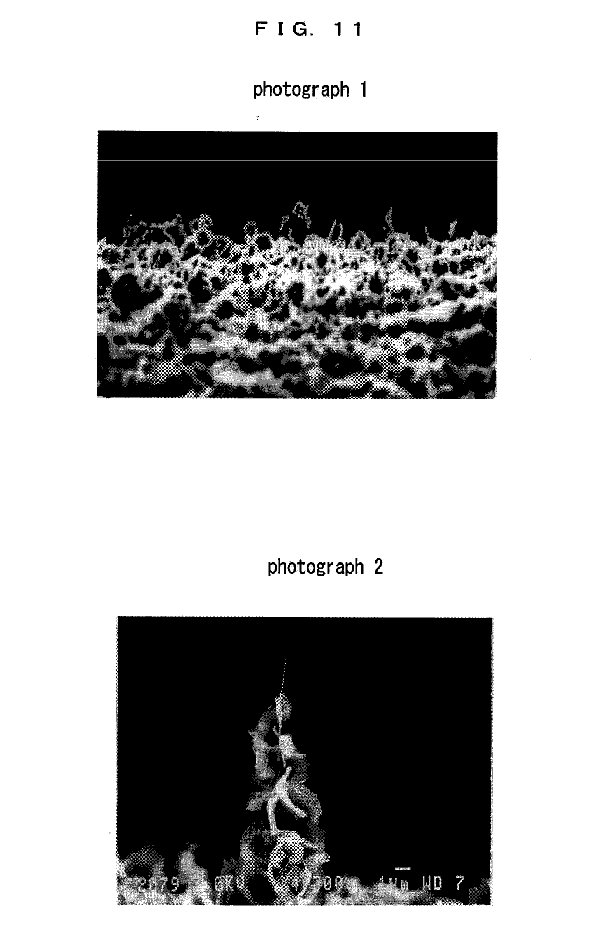

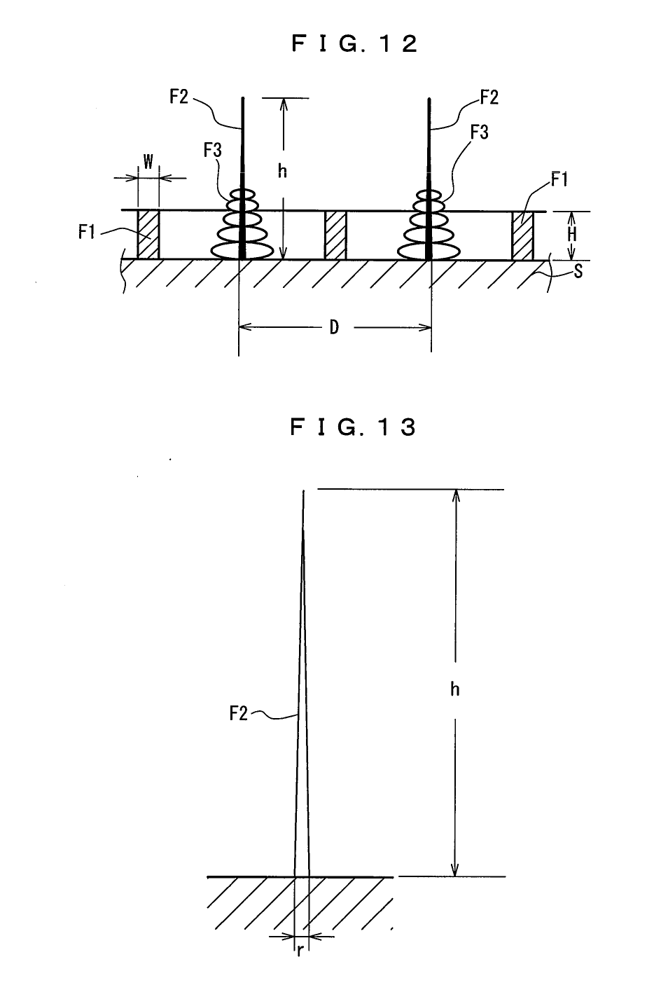

FIG. 12 is a schematic view of a structure of the carbon film shown in the SEM photographs. The conditions of the film deposition are as follows: flow amount of methane gas is 5 ccm; flow amount of hydrogen gas is 300 ccm; direct-current power is 3,000 W; high-frequency power is 500 W; temperature of conductive wire 22 is 750° C.; pressure of chamber 12 is 2,000 Pa; bias is −120 V; and deposition time is 10 minutes.

The carbon film comprises a net-shape carbon film F1, one or a plurality of needle-shape carbon films F2 surrounded by the net-shape carbon film F1, and a wall-shape carbon film F3 formed in such a manner that the film gets entangled along the net-shape carbon film F2 from a lower part to an intermediate position thereof. The needle-shape carbon film F2 has such a shape that its radius is reduced from an arbitrary position towards an edge thereof.

More specifically, in the needle-shape carbon film F2, an electric field concentration coefficient β in the formula of Fowler-Nordheim is expressed as the formula of h/r provided that a radius at the arbitrary position and a height from the arbitrary position to the edge thereof are respectively r and h. Further, the needle-shape carbon film F2 has such a shape that the radius thereof is reduced from the arbitrary position to the edge thereof.

The net-shape carbon film F1 is continuously formed on a substrate S. When observed from a plane direction, an entire shape of the film is substantially a net shape. The height (H) of the net-shape carbon film F1 is substantially at most 10 nm, and the width (W) of the net-shape carbon film F1 is approximately 4 nm through 8 nm. In the region on the substrate 2 surrounded by the net-shape carbon film F1, the needle-shape carbon film F2 extends like a needle and has its edge, in which the field is concentrated to form an electron emitting point from which the electrons are emitted. Since the needle-shape carbon film F2 is surrounded by the net-shape carbon film F1, a distance between electron emitting points is restricted or defined.

The needle-shape carbon film F2 is formed so as to have a height (h) higher than the height (H) of the net-shape carbon film F1, which is, for example, approximately 60 μm. The wall-shape carbon film F3, when observed from a side surface thereof, has such a shape that its width substantially increases toward its bottom. The shape is, for example, a tapered shape. However, the shape is not exactly a tapered shape in terms of the geometry, and the term a tapered shape is used only for easy understanding. The shape of the film is actually horizontally wide, spiral or of any other similar form. In any of the shapes, the wall-shape carbon film F3 makes a good contact with the substrate S in a large bottom area so that the needle-shape carbon film F2 can be mechanically firmly supported with respect to the substrate S and an electrical contact of the needle-shape carbon film F2 with respect to the substrate S can be sufficiently obtained.

In the case of the carbon film according to the present preferred embodiment thus constituted, though an aspect ratio of the needle-shape carbon film F2 is large as carbon nanotube, the wall-shape carbon film F3 is formed so as to extend and get entangled like a wall along the needle-shape carbon film F2 from the lower part to the intermediate position thereof. Therefore, the needle-shape carbon film F2 can be mechanically firmly supported with respect to the substrate S, and is resistant to falling down on the substrate S. As a result, a stability can be improved as an electron emitting source of an illumination lamp, and an electron emitting characteristic of the illumination lamp required as the electron emitting source of the illumination lamp can be obtained because the electrical contact with respect to the substrate for supplying the current can be made by the wall-shape carbon film F3 though the diameter of the needle-shape carbon film F2 is thin.

Further, in the carbon film, a potential surface around the edge of the needle-shape carbon film F2 drastically changes, and the field is thereby intensely concentrate, while the field concentration does not occur in the net-shape carbon film F1. Further, a needle-shape carbon film F2 is separated from an adjacent needle-shape carbon film F2 by the net-shape carbon film F1 by an appropriate space (D), for example, approximately 100 μm, so that the field concentration effects of the respective films do not interfere with each other. Because the needle-shape carbon film F2 is not formed as closely as the conventional carbon nanotube, the gathering of needle-shape carbon films F2 has only a little effect on their field concentration at every net-shape carbon film F1.

In the carbon film structure according to the present preferred embodiment, the field is likely to be concentrated in the needle-shape carbon film F2. Then, the needle-shape carbon film F2 is surrounded by the net-shape carbon film F1 formed on the substrate S, which restricts the space between the needle-shape carbon films F2. Accordingly, the problem that a large number of needle-shape carbon films F2 are closely formed can be circumvented, and full use can be made of performance of the field concentration of each needle-shape carbon film F2. As a result, superior electron emitting characteristic can be provided.

The electrons can be stably emitted because the position of the needle-shape carbon film F2 on the substrate S is remarkably stabilized by the wall-shape carbon film F3. Further, directions in which the plurality of needle-shape carbon films are formed can be easily aligned. Accordingly, the electrons can be evenly emitted from the plurality of needle-shape carbon films F2 across the entire substrate. When the needle-shape carbon film F2 is used in the field emission illumination lamp as the cathode electron source, therefore, the phosphors inside the lamp can emit light with an even brightness. Further, since the needle-shape carbon film F2 is mechanically firmly supported by the wall-shape carbon film F3 with respect to the substrate S, the film F2 is unlikely to fall down on the substrate S. As a result, the stability as the electron emitting source of the illumination lamp can be improved. Further, the electrical contact of the needle-shape carbon film F2 with respect to the substrate for supplying the current can be made by the wall-shape carbon film F3.

The needle-shape carbon film F2 has such a needle shape that the electric field concentration coefficient β is expressed as the formula of h/r provided that the radius at the arbitrary position and the height from the arbitrary position to the edge thereof are respectively r and h, and the radius is reduced toward the edge. Thus, the needle-shape carbon film F2 is such a carbon film that the field emission becomes hardly saturated.

Still Another Example of Plasma Generating Device

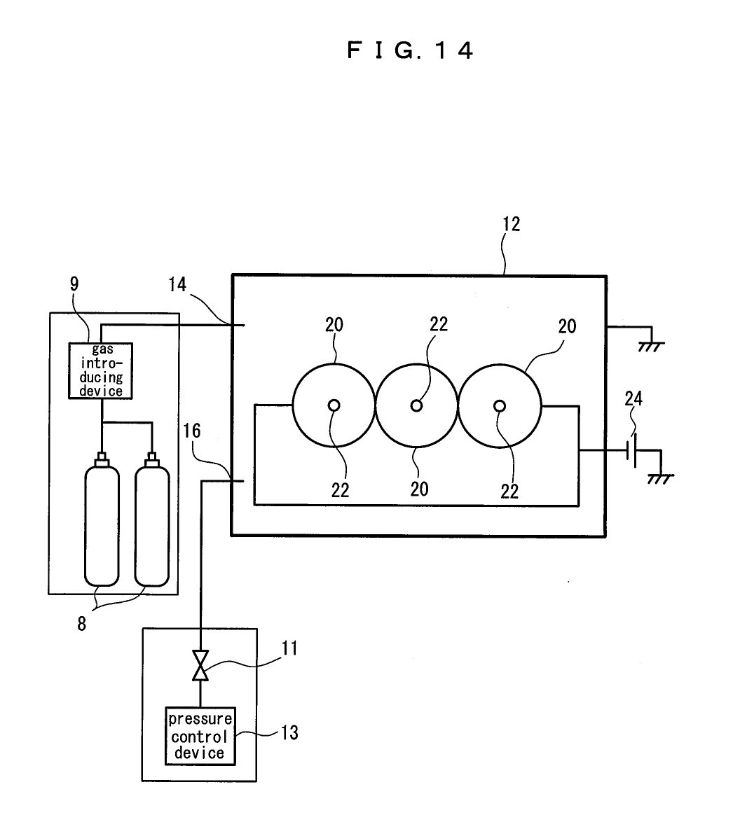

FIG. 14 shows still another example of the plasma generating device. The plasma generating device is incorporated in a film deposition device. The film deposition device is adapted to introduce gas for generating plasma from the gas cylinder 8 into the chamber 12 via the introducing section 14 after the pressure and flow amount of the gas are adjusted by a pressure/flow amount adjusting circuit 9.

The vacuum exhaust system 13 is connected to the exhausting section 14 of the chamber 12 via the exhaust control valve 11 so that the internal pressure of the chamber 12 is adjusted. The pressure inside the chamber 12 is controlled depending on the opening degree of the exhaust control valve 11 under the control by the vacuum exhaust system 13.

In the chamber 12, the cylindrical electrodes 20 are provided adjacent to one another so that outer peripheral surfaces thereof are in electrical contact with one another. These cylindrical electrodes 20 are formed from a metal net (mesh) wound in a cylindrical shape. The conductive wire 22, which is an example of the film deposition target, is placed inside each of the cylindrical electrodes 20.

The negative potential of the direct-current power source for exciting the plasma is applied to the cylindrical electrodes 20. The positive electrode of the direct-current power supply 24 is grounded, and the chamber 12 is grounded. The direct-current power supply 24 can be variably adjusted, in the voltage range of, for example, 100-2,000 V.

In the film deposition device thus constituted, when the internal pressure of the chamber 12 is reduced in the foregoing pressure range so that the gas is introduced from the gas introducing section 14, and the negative potential of the direct-current power supply 24 is applied to the cylindrical electrodes 20, plasma is generated in the inside of each of the cylindrical electrodes 20, which dissolves the gas. As a result, the film is formed on the surface of the conductive wire 22.

As described, in the present plasma generating device, wherein the plurality of cylindrical electrodes are provided adjacent to one another, the plasma can be sealed into the inside of each of the cylindrical electrodes with an evenly high density without any leakage.

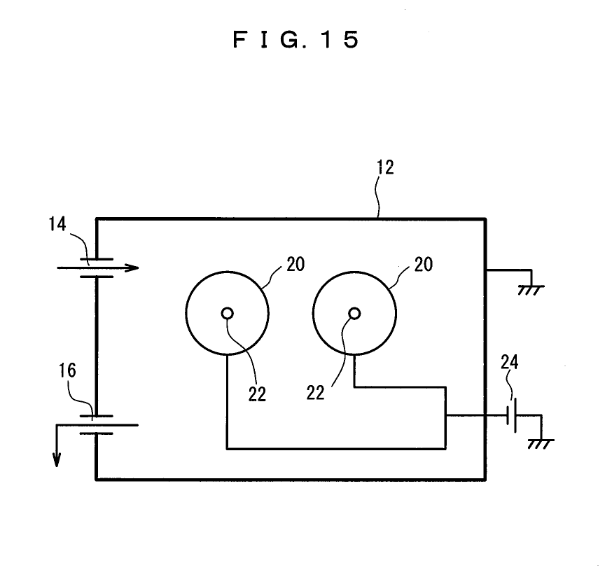

In the plurality of cylindrical electrodes 20, even in the case where they are distant from each other as shown in FIG. 15, the plasma can be generated in the inside of each of the cylindrical electrodes 20 when the same negative voltage is applied thereto from the direct-current power supply 24.

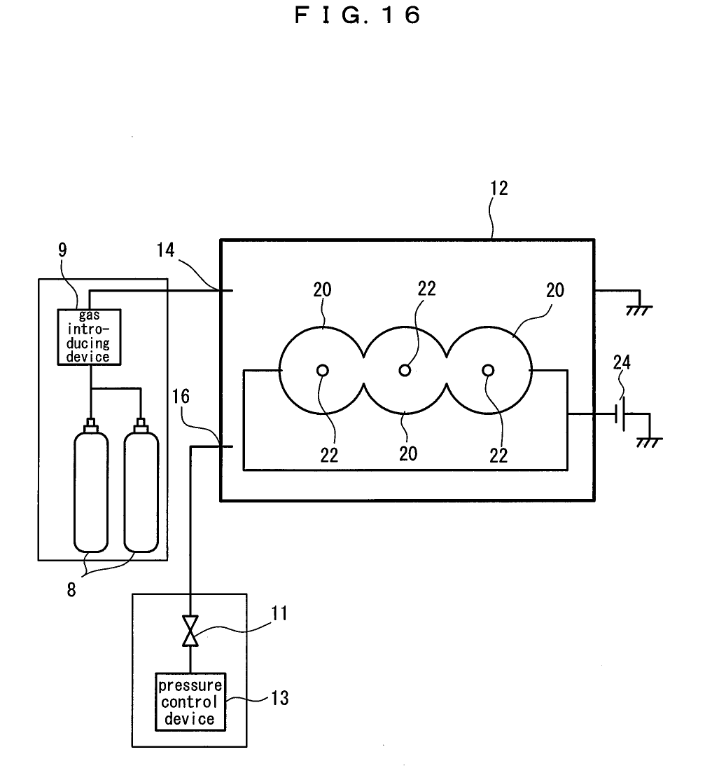

The plurality of cylindrical electrodes 20 shown in FIG. 14 are provided adjacent to one another in such an independent manner that internal parts thereof are separated from one another. The plurality of cylindrical electrodes 20 may be provided adjacent to one another in a continuous manner as shown in FIG. 16.

The sectional surface of the cylindrical electrode 20 may be circular, polygonal, elliptical or of any other shape. A large number of cylindrical electrodes 20 may be provided in the chamber.

In the plasma generating device so far described, wherein the conductive wire 22, for example, is provided in the inside of each of the cylindrical electrodes 20, the plasma is generated in each of the cylindrical electrodes 20, and the gas is introduced thereinto, so that a film having an even thickness and a high quality can be formed on the entire surfaces of the conductive wires 22. As a result, the present invention can contribute to the mass production of any product in which the conductive wire 22 can be used.

Still Another Example of Plasma Generating Device

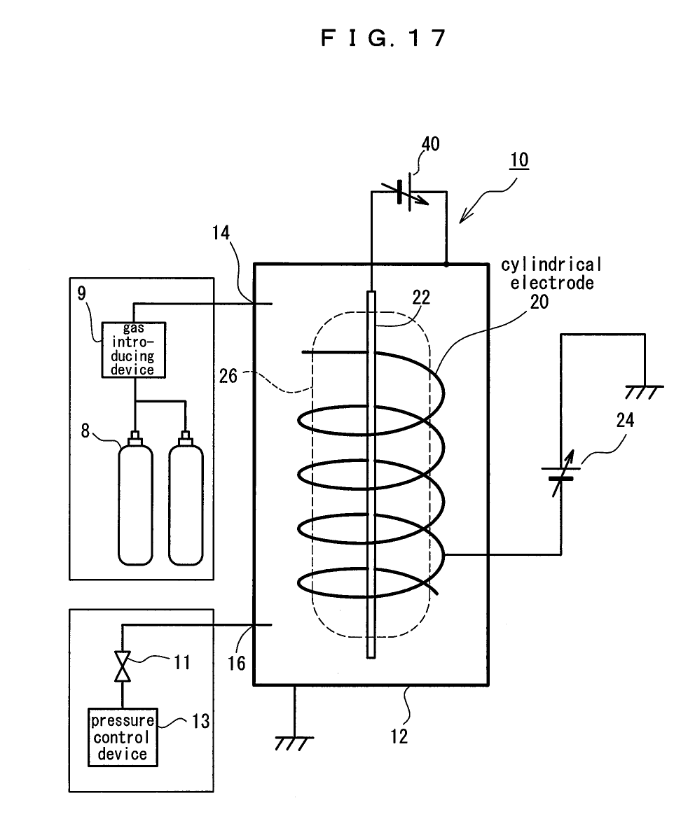

FIG. 17 shows still another example of the plasma generating device 10 provided with a bias power supply 40. A negative electrode of the bias power supply 40 is connected to the conductive wire 22 as the film deposition target, while a positive electrode thereof is connected to the chamber 12 and grounded.

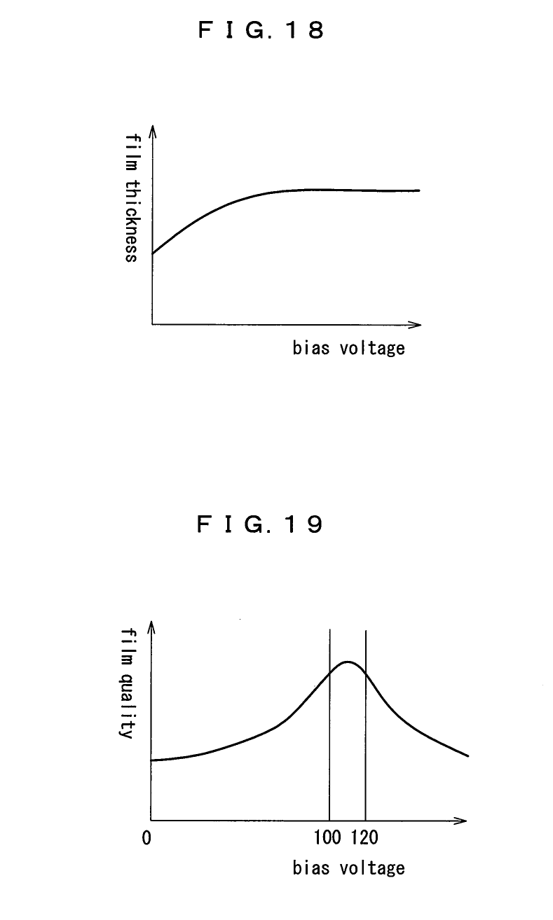

FIG. 18 is a graph in which a voltage of the bias power supply 40 is shown in a horizontal axis and a speed at which a film is deposited on the surface of the conductive wire 22 is shown in a vertical axis. As shown in FIG. 18, as the voltage of the bias power supply 40 is increased, the speed at which the film is deposited on the surface of the conductive wire 22 can be increased.

FIG. 19 is a graph in which the voltage of the bias power supply 40 is shown in a horizontal axis and a quality of the film deposited on the surface of the conductive wire 22 is shown in a vertical axis. As shown in FIG. 19, when the voltage of the bias power supply 4 is adjusted to stay in the range of, for example, 100-200 V, the film quality can be improved.

### INDUSTRIAL APPLICABILITY

The plasma generating device according to the present invention can generate plasma having a long length on a long film deposition target, and perform different types of film deposition by controlling pressure and selecting a type of gas.

1-16. (canceled)

17. A plasma generating device provided with a cylindrical electrode in the vacuum inside thereof, the plasma generating device introducing gas into the cylindrical electrode and applying a direct-current negative voltage to the cylindrical electrode as a plasma generating voltage, comprising:
a gas introducing device capable of selecting gas corresponding to a type of film deposition and introducing the selected gas into the cylindrical electrode; and
a pressure control device capable of controlling an internal pressure of the cylindrical electrode depending on a type of film deposition, wherein
the gas is selected by the gas introducing device and the internal pressure of the cylindrical electrode is controlled by the pressure control device, so that:
the plasma generating device can be used as a PVD device for forming a film on a surface of a film deposition target by sputtering a material constituting the cylindrical electrode through the introduction of non-reactive gas and low-pressure control;
the plasma generating device can be used as a reactive PVD device for forming the film on the surface of the film deposition target by sputtering the material constituting the cylindrical electrode through the introduction of reactive gas and low-pressure control; and
the plasma generating device can be used as a plasma CVD device for forming a carbon film on the surface of the film deposition target through the introduction of gas for carbon film deposition and high-pressure control.

18. The plasma generating device as claimed in claim 17, wherein
the cylindrical electrode comprises a peripheral wall whose shape is at least a coil shape, a net shape, a barrier shape or a basket shape.

19. The plasma generating device as claimed in claim 17, wherein
the cylindrical electrode is open at each end and extends toward both ends in accordance with the film deposition target.

20. The plasma generating device as claimed in claim 17, wherein
a voltage in which a high-frequency voltage is superposed on the direct-current negative voltage is applied to the cylindrical electrode.

21. The plasma generating device as claimed in claim 17, wherein
a plurality of cylindrical electrodes are provided adjacent to each other in such a manner that internal parts thereof are continuous.

22. The plasma generating device as claimed in claim 17, wherein
a bias voltage is applied to the film deposition target placed inside the cylindrical electrode.

23. A plasma generating method, wherein the plasma generating device as claimed in claim 17 is used, comprising:
a first step for placing the film deposition target inside the cylindrical electrode;
a second step for reducing an internal pressure of the cylindrical electrode;
a third step for introducing the gas into the cylindrical electrode; and
a fourth step for applying direct-current negative voltage to the cylindrical electrode.

24. The plasma generating method as claimed in claim 23, further comprising a fifth step for applying a bias voltage for controlling a film deposition speed to the film deposition target.

25. The plasma generating method as claimed in claim 23, further comprising a sixth step for applying a bias voltage for controlling a film quality to the film deposition target.

26. The plasma generating method as claimed in claim 23, wherein a high-frequency voltage is superposed on the direct-current negative voltage in the fourth step.

27. The plasma generating method as claimed in claim 23, further comprising a seventh step for placing the film deposition target inside the cylindrical electrode and heating the film deposition target by an alternate-current power supply.
